(19) United States
(12) Patent Application Publication
(10) Pub. No.: US 2025/0245410 A1
(43) Pub. Date: Jul. 31, 2025

(54) METHOD AND SYSTEM EMPLOYING LINEAR DISTANCE MARKER-BASED DESIGN LAYOUT ANALYSIS

(71) Applicant: GlobalFoundries U.S. Inc., Malta, NY (US)

(72) Inventors: David Charles Pritchard, Schenectady, NY (US); Romain H.A. Feuillette, Williston, VT (US); Collin A. Tranter, Clifton Park, NY (US); Navneet K. Jain, Milpitas, CA (US); Mahbub Rashed, Cupertino, CA (US); James A. Culp, New Paltz, NY (US)

(21) Appl. No.: 18/423,385

(22) Filed: Jan. 26, 2024

(51) Int. Cl. G06F 30/392; G06F 30/398

(52) U.S. Cl. CPC G06F 30/392; G06F 30/398

(57) ABSTRACT

Disclosed design methods and systems employ linear distance marker(s) (LDM(s)) placed over a layout (e.g., of a device or cell) to be analyzed. Nodes are inserted into LDM(s) at intersections with edges of layout shapes. Node-to-node distances (d) for node-to-node segments on LDM(s) are calculated. Design rules with distance specifications (D) are identified and assigned to the segments. A first table is generated and includes, for each segment, the design rule, d, and D. A second table is generated and includes, for each segment in a user-specified subset of segments, the design rule and either D or a user-specified compacted distance specification (C). An output table is generated and includes, for each segment in the subset, the design rule, d, and either D or C. The output table can be analyzed manually and/or automatically to determine if compaction is feasible. Additional embodiments use LDMs to profile devices within a layout.

### BACKGROUND

The present disclosure relates integrated circuits and, more particularly, to embodiments of design methods and systems that employ software tools to facilitate design-technology co-optimization (DTCO).

Factors considered in modern IC design include, but are not limited to, performance improvement, power consumption, and size scaling. Typically, design rules established for a particular processing technology provide a trade-off between size scaling and yield. In DTCO, design and the particular processing technology (i.e., the foundry services) are optimized together to improve performance, power, and area (PPA) as well as other factors (e.g., cost). However, currently to enable further size scaling of an IC component (e.g., a device, group of devices, or standard cell) over what is allowable according to established design rules, the design layout is analyzed in a piecewise, often error-prone, and time-consuming manner.

### SUMMARY

Disclosed herein are embodiments of computer-aided design (CAD) methods that facilitate DTCO and/or layout profiling.

In some embodiments, the method can include calculating, by a processor, node-to-node distances for node-to-node segments on a linear distance marker overlaying a layout for an integrated circuit component, where the nodes are located at intersections between the linear distance marker and edges of shapes in the layout. The method can further include generating, by the processor, a first table including design rules applicable to the node-to-node segments, respectively. The first table can further include node-to-node distance specifications and the node-to-node distances for the node-to-node segments, respectively. The method can further include generating, by the processor, an output table. The output table can include, for each node-to-node segment of a subset of the node-to-node segments, a corresponding node-to-node distance, a corresponding design rule, and one of a corresponding distance specification and a corresponding compacted distance specification.

In other embodiments, the method can include placing, by a processor executing a machine learning tool, multiple linear distance markers over a layout for an integrated circuit component. The method can further include calculating, by the processor, node-to-node distances for node-to-node segments on the linear distance markers, where the nodes are located at intersections between the linear distance markers and edges of shapes in the layout. The method can include generating, by the processor, a first table including design rules applicable to the node-to-node segments, respectively. The first table can further include distance specifications and the node-to-node distances for the node-to-node segments, respectively. The method can further include generating, by the processor, an output table. This output table can include, for each node-to-node segment of a subset of the node-to-node segments, a corresponding node-to-node distance, a corresponding design rule, and one of a corresponding distance specification and a corresponding compacted distance specification. The method can further include establishing, by the processor, an iterative machine learning feedback loop where the machine learning tool receives the output table and repeats the placing of the linear distance markers.

In still other embodiments, the method can include placing, by a processor, a grid over a layout for at least a section of an integrated circuit that has been displayed on a display monitor via the GUI. The grid includes linear distance markers arranged in a first direction and in a second direction perpendicular to the first direction. The method can further include calculating, by the processor, node-to-node distances for node-to-node segments on the linear distance markers of the grid overlaying the layout, where the nodes are located at intersections of the linear distance markers and edges of shapes in the layout. The method can include generating, by the processor, a table including design rules applicable to the node-to-node segments, respectively. This table can further include distance specifications and the node-to-node distances for the node-to-node segments, respectively. The method can further include evaluating, by the processor, the table and process design kit information to identify components within the layout. The method can further include generating, by the processor, a profile of the components in the layout.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating a computer-aided design (CAD) system that can be employed to implement the disclosed method embodiments;

FIG. 2 is a flow diagram illustrating a disclosed embodiment of a method;

FIGS. 3.1-3.6 are examples of graphic user interface (GUI) screen shots that could be generated during performance of the method of FIG. 2;

FIGS. 4.1-4.6 are additional examples of GUI screen shots that could be generated during performance of the method of FIG. 2;

FIG. 5 is a flow diagram illustrating another disclosed embodiment of a method;

FIG. 6 is an example of a GUI screen shot that could be generated during performance of the method of FIG. 5;

FIG. 7 is a flow diagram illustrating another disclosed embodiment of a method;

FIG. 8 is an example of a GUI screen shot that could be generated during performance of the method of FIG. 7; and

FIG. 9 is a schematic diagram illustrating an example of a hardware environment that can be used to implement aspects of disclosed system, method and computer program product embodiments.

### DETAILED DESCRIPTION

As mentioned above, factors considered in modern IC design include, but are not limited to, performance improvement, power consumption, and size scaling. Typically, design rules established for a particular processing technology provide a trade-off between size scaling and yield. In DTCO, design and the particular processing technology (i.e., the foundry services) are optimized together to improve performance, power, and area (PPA) as well as other factors (e.g., cost). However, currently, to enable further size scaling of an IC component (e.g., a device, group of devices, or standard cell) over what is allowable according to established design rules, the design layout is analyzed in a piecewise, often error-prone, and time-consuming manner.

In view of the foregoing, disclosed herein are embodiments of computer-aided design (CAD) methods and systems that employ a unique design layout tool configured for linear distance marker (LDM)-based layout analysis to facilitate DTCO (e.g., to facilitate size scaling during integrated circuit (IC) design or during design of standard or parameterized cells to be included in a cell library) and/or layout profiling. Specifically, in the disclosed embodiments, one or more LDMs can be placed over a design layout (e.g., for a device, a group of devices, a cell, etc.) to be analyzed. Nodes can be inserted into the LDM(s) at intersections with edges of layout shapes. Node-to-node distances (d) for node-to-node segments, respectively, on the LDM(s) can be calculated (e.g., based on node coordinate information). Design rules (e.g., overlay, space, or width) with corresponding distance specifications (D) (i.e., technology requirements) can be identified and assigned to the node-to-node segments, respectively. A first table can be generated and can include, for each node-to-node segment, the applicable design rule, d, and D. Additionally, a second table can be generated based on user inputs and can include, for each node-to-node segment in a user-specified subset of the node-to-node segments, the applicable design rule and either D or a user-specified compacted distance specification (C). Finally, an output table can be generated based on a combination of information found in the first and second tables and can include, for each node-to-node segment in the subset, the applicable design rule, d, and either D or C (as specified in the second table). The output table can subsequently be analyzed manually and/or by the tool (e.g., to determine whether or not layout compaction is feasible). Such an output table facilitates fast statistical iterative analysis. Additional embodiments can use LDMs (e.g., patterned in a grid) and overlaid across a design layout (e.g., of an entire IC or section thereof) to profile devices (i.e., to identify the various devices) within the design layout based on inputs from a process design kit (PDK).

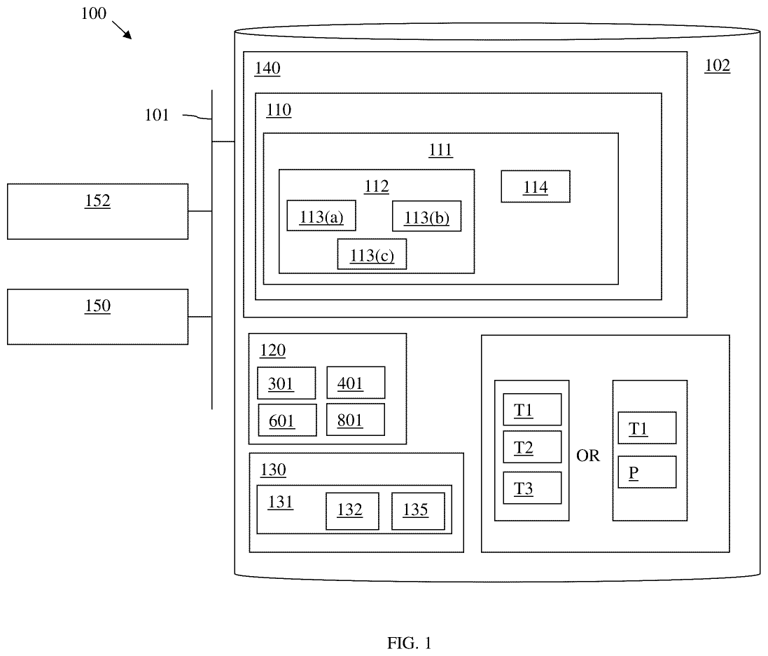

More particularly, FIG. 1 is a schematic diagram illustrating disclosed embodiments of a computer-aided design (CAD) system 100. CAD system 100 can include multiple system components. These system components can include, but are not limited to, one or more processors 150, one or more display monitors 152, and one or more computer readable storage mediums 102. The system components can be interconnected over a system bus 101 (as illustrated) and/or over a wired or wireless network. For purposes of illustration, CAD system 100 is described below and illustrated in FIG. 1 as having a single processor and a single storage medium. However, it should be understood that FIG. 1 is not intended to be limiting. Alternatively, CAD system 100 could incorporate multiple processors for performing one or more of the different processes in a design flow and/or multiple storage mediums, which are accessible by the processor(s) and which store the required data, software tools, etc. for performing the different processes in the design flow. Furthermore, all system components can be co-located. Alternatively, the various system components can be incorporated into a distributed system whose components are located on different networked computers.

Storage medium 102 can store electronic design automation (EDA) tool(s) 130 (e.g., specialized software program(s)). Each EDA tool 130 includes program instructions that are executable by processor 150 to cause processor 150 to perform process steps in a computer-aided integrated circuit (IC) design flow. Various EDA tools 130 for use in IC design are well known in the art and, thus, the details thereof have been omitted from this specification in order to allow the reader to focus on the salient aspects of the disclosed embodiments. However, at least one of the EDA tools 130 stored by storage medium 102 and accessible by processor 150 can be a novel design layout analysis tool 131 (also referred to herein as a design layout analyzer), which includes program instructions that are executable by processor 150 to cause processor 150 to at least perform a method of analyzing and, optionally, editing (e.g., compacting) a design layout as described in greater detail below.

Storage medium 102 can further store design information 140, which is accessible and usable by one or more EDA tools 130 (including design layout analysis tool 131) during performance of the IC design flow. Design information 140 can include design information technology files for a specific technology node, design rule decks for the specific technology node (e.g., in a design rules database 111), various libraries, etc. Optionally, design information 140 can be in the form of a process design kit (PDK) 110. A PDK 110 is a set of electronic files including both data and script files. A PDK is typically developed by a semiconductor foundry for its customers in order to facilitate design of ICs at a specific processing technology node supported by the foundry. The electronic files within the PDK are accessible by one or more EDA tools executed on a CAD system at different stages in the design flow. Exemplary PDK electronic files include, but are not limited to, simulation models, symbols and technology files for the specific technology node, a cell library, and design rule decks (also referred to herein as a design rules database 111). PDK 110 can also include, for example, a table 114 of devices or other IC components available in the specific technology node. PDKs are well known in the art and, thus, the details thereof have been omitted from the specification in order to allow the reader to focus on the salient aspects of the disclosed embodiments.

As mentioned above, design information 140 (e.g., PDK 110) can include design rule decks (e.g., in a design rules database 111). Each rule deck or set of design rules in the database is applicable to one or more of the particular processes in the design flow including, but not limited to, layout generation. Those skilled in the art will recognize that the design rules are determined based on process assumptions associated with the specific technology node at issue (e.g., critical dimensions at the different fabrication levels, expected results of process steps given the critical dimensions, etc.), based on various fail mechanisms that can occur in light of those process assumptions, etc. In the disclosed embodiments, a subset 112 of the design rules included in the design rules database 111 can be shape-dependent and can include, but are not limited to, design rules that establish distance specifications (i.e., technology requirements) for the widths of specific types of shapes in a layout (i.e., width rules 113(a)), for the size of spaces between shapes of the same or different types in a layout (i.e., space rules 113(b)), and for amount of allowable overlap between shapes of the same or different types in a layout (i.e., overlap rules 113(c)).

Storage medium 102 can further store one or more previously generated design layouts 120 (e.g., 301, 401, 601, 801, as discussed in greater detail below with regard to specific embodiments) for ICs or portions thereof. For example, a previously generated design layout can be for a device (e.g., a field effect transistor (FET), bipolar junction transistor (BJT), capacitor, a resistor, or any other type of device the can be implemented in an IC design at the particular technology node). A previously generated design layout can be for a group of devices that can be implemented in an IC design at the particular technology node (e.g., a circuit component including multiple interconnected devices of the same or different types). A previously generated design layout can specifically be for a cell under design (i.e., a cell layout). Those skilled in the art will recognize that a cell represents an IC component. The IC component can be a single device (e.g., a transistor, capacitor, resistor, etc.) or other feature (e.g., an isolation region, etc.) or multiple interconnected devices (e.g., a logic gate) or features. Final cell designs are stored in cell library and are available for selection and placement during subsequent IC design. Such cells can be standard cells with fixed parameters or parameterized cells (Pcells) with user-selectable parameters. Such cells are well known in the art and, thus, the details thereof have been omitted from this specification in order to allow the reader to focus on the salient aspects of the disclosed embodiments.

As mentioned above, design layout analysis tool 131 can at least include program instructions that are executable by processor 150 to cause processor 150 to perform a method of analyzing and, optionally, editing (e.g., compacting) a previously generated design layout. That is, this design layout analysis tool 131 can be a discrete EDA tool. Alternatively, it could be included as a sub-tool within a design layout generating tool (also referred to herein as a design layout generator). The design layout analysis tool 131 can further include a graphic user interface (GUI) 132. This GUI 132 can be displayed on monitor 152 and can be configured to allow a user to interact with the design layout analysis tool 131, as discussed in greater detail below.

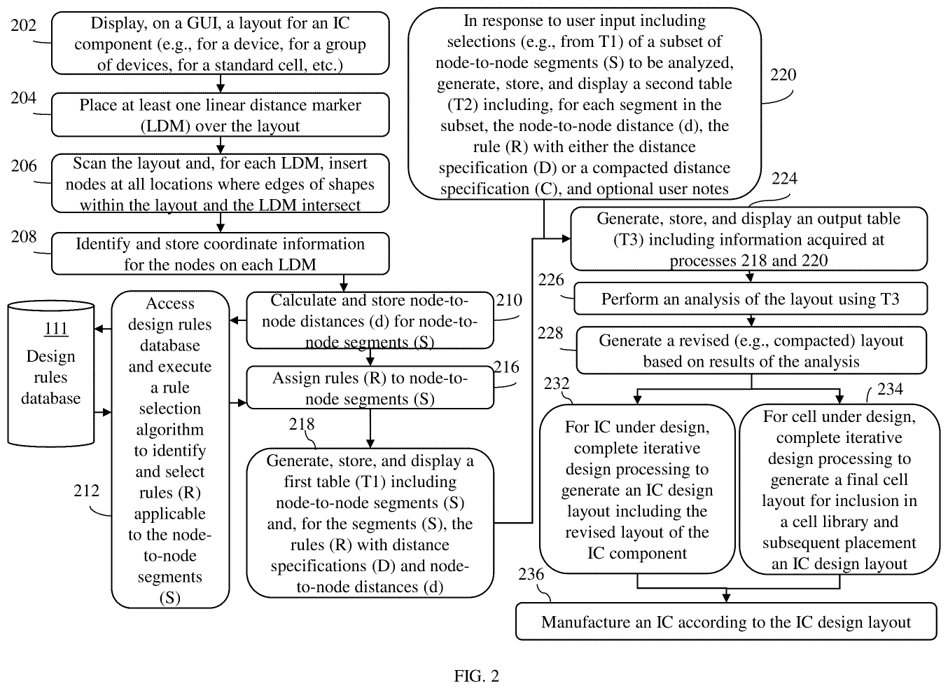

FIG. 2 is a flow diagram illustrating an embodiment of a CAD method that, in conjunction with the above-described CAD system 100 of FIG. 1, employs such a design layout analysis tool 131.

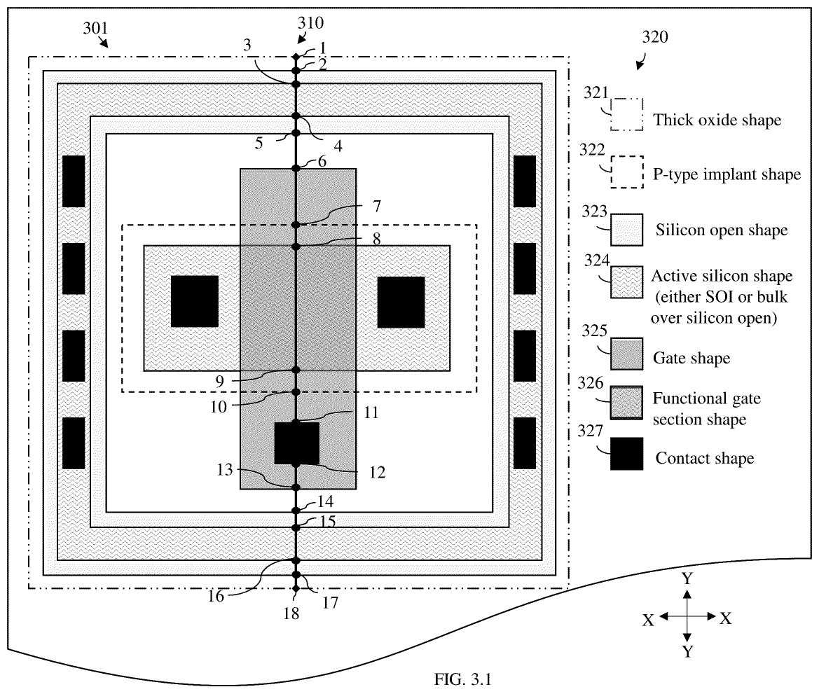

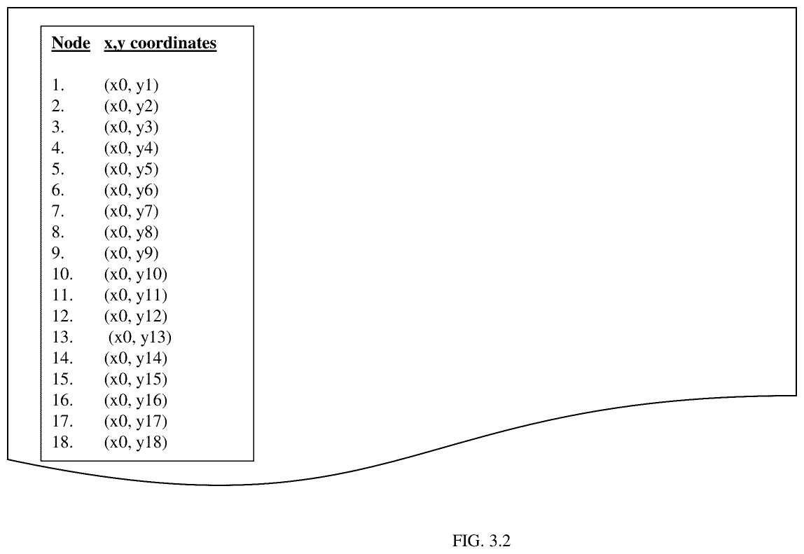

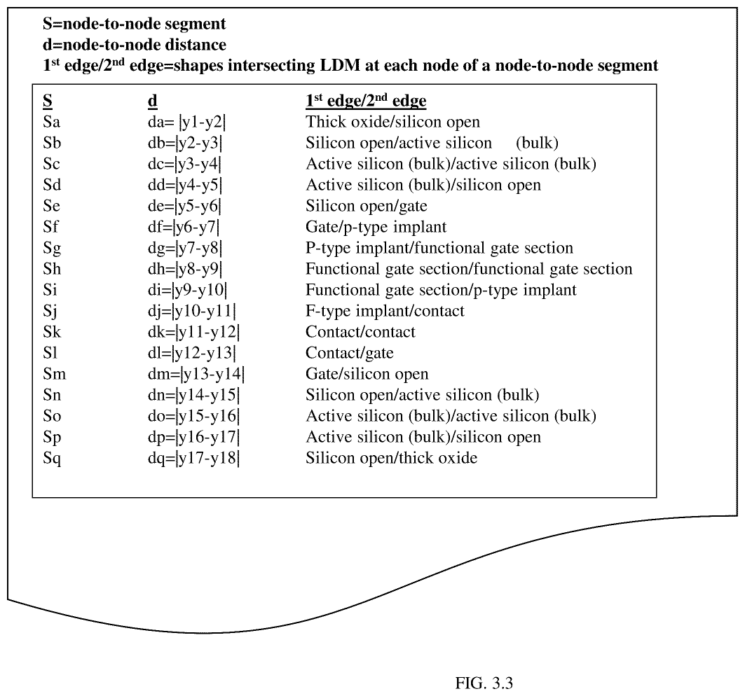

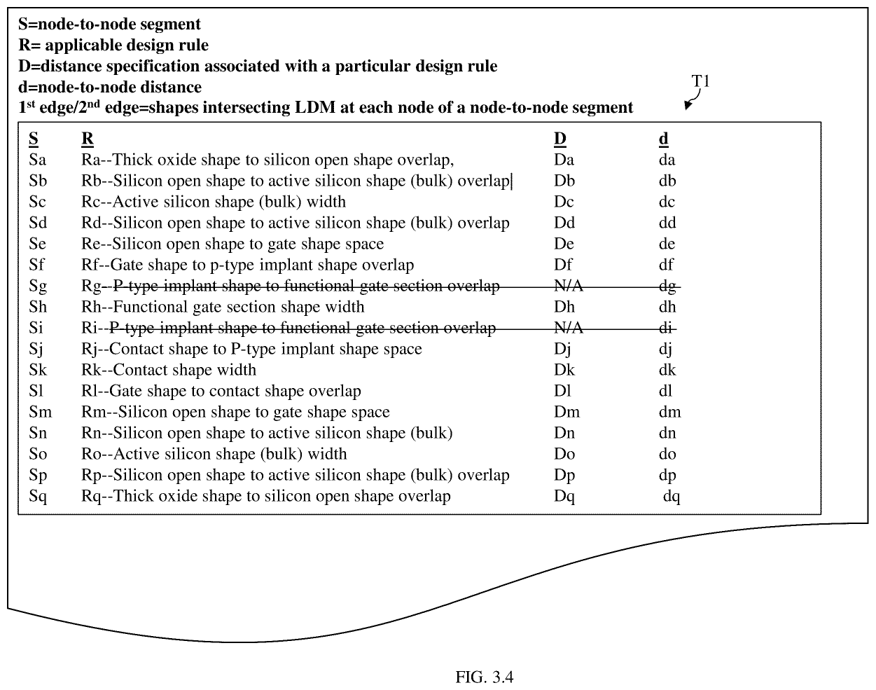

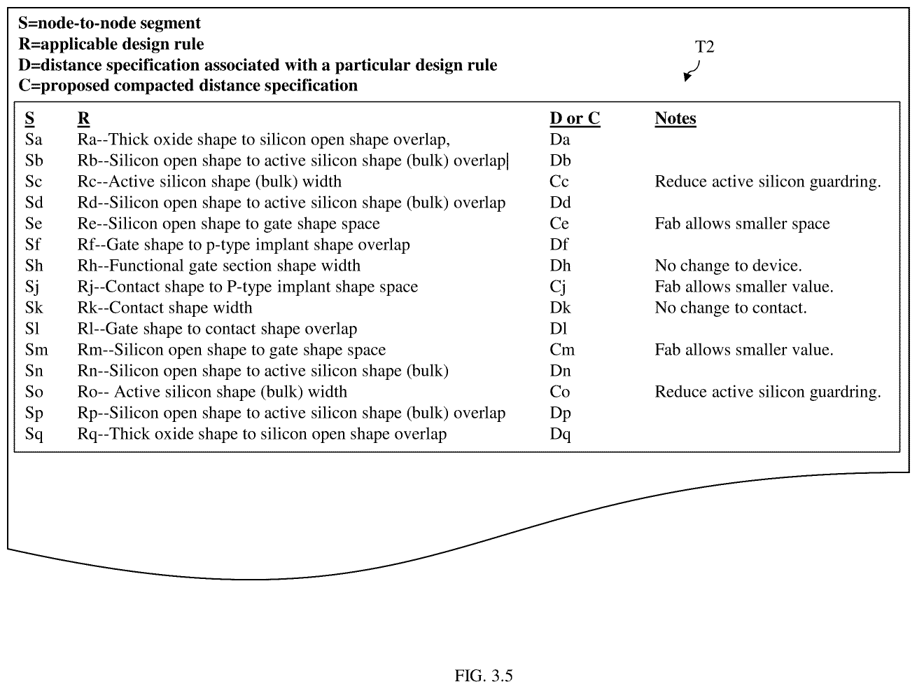

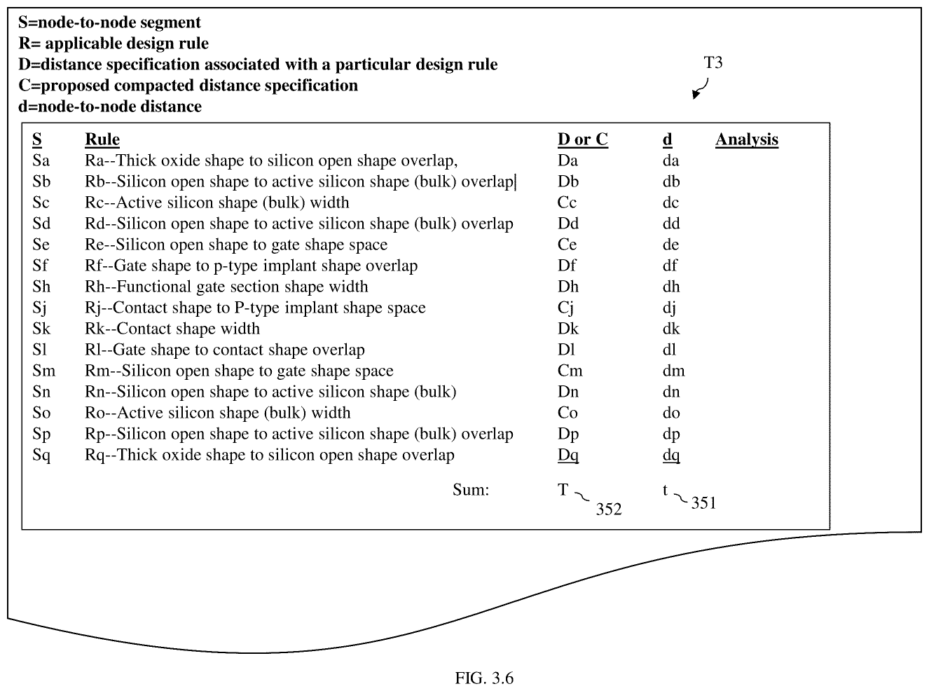

FIGS. 3.1-3.6 illustrate one example of implementation of the method of FIG. 2. Referring to FIG. 2 in combination with FIGS. 3.1-3.6, the method can include, in response to user inputs (e.g., designer inputs via GUI 132), displaying a previously generated design layout 301 to be analyzed (see process 202 and FIG. 3.1). For purposes of illustration, design layout 301 represents a single field effect transistor (FET) implemented in fully-depleted silicon-on-insulator (FDSOI). Shapes 320 in the design layout 301 include a thick oxide shape 321, a p-type implant region shape 322, a silicon open shape 323, an active silicon shape 324 (e.g., either in SOI or in a bulk region of the FDSOI structure), a gate shape 325, a functional gate section shape 326 (which defines the shape of the FET channel region), and a contact shape 327 (e.g., either on active silicon (SOI) or on active silicon (bulk)).

The method can include placing a linear distance marker (LDM) 310 (also referred to herein as an ARC) over at least a portion of design layout 301 shown on GUI 132 (see process 204 and FIG. 3.1). Placement of LDM 310 can, for example, be performed by processor 150 in response to user-inputs (via GUI 132) that define end points of LDM 310. Alternatively, placement of LDM 310 could be in response to user-selection (e.g., via a drop down menu of GUI 132) of a particular axis through design layout 301, such as a center vertical axis (as illustrated), a center horizontal axis, or any other axis through design layout 301. Alternatively, placement of LDM 310 could be automatic according to a pre-define sequence used in an iterative process in which an analysis is performed with respect to placement of the LDM at a first location in a sequence, then performed again with placement of the LDM at a second location in a sequence, and so on.

The method can include scanning design layout 301 to identify all locations where edges of any of the shapes 320 in the design layout 301 intersect LDM 310 and further inserted nodes (e.g., see nodes 1-18) into LDM 310 at each of the intersecting locations (see process 206 and FIG. 3.1). For example, node 1 is at the intersection of LDM 310 and an edge of thick oxide shape 321, node 2 is at the intersection of LDM 310 at an edge of silicon open shape 323, and so on. Process 216 can be performed by processor 150 (e.g., automatically or in response to a user request via GUI 132).

The method can further include identifying x,y coordinate information for nodes 1-18 on LDM 310 (see process 208 and FIG. 3.2). For example, a standard measurement grid could be employed with the center vertical axis in the y-direction and a center horizontal axis in the x-direction. Thus, in the example provided where LDM 310 is on the center vertical axis the x-coordinate for all nodes will be zero and y-coordinate information can be determined according to the measurement grid. Process 208 can also include storing the x, y coordinate information (e.g., in storage medium 102) for use in subsequent processing and, optionally, displaying the coordinate information via GUI 132. Process 208 can be performed by processor 150 (e.g., automatically or in response to a user request via GUI 132).

The method can further include calculating node-to-node distances (d) for each node-to-node segment (S) (i.e., distances da-dq for segments Sa-Sq) on LDM 310 using the previously determined coordinate information (see process 210 and FIG. 3.3). For purposes of this disclosure, a node-to-node segment (S) refers to a segment of an LDM between two adjacent nodes and the node-to-node distance (d) is a distance measurement between the two adjacent nodes. Node-to-node segment Sa extends from node 1 to node 2 and the node-to-node distance (da) for Sa is equal to the absolute value of the y-coordinate for node 1 (i.e., y1) minus the y-coordinate for node 2 (i.e., y2); node-to-node segment Sb extends from node 2 to node 3 and the node-to-node distance db for Sb is equal to the absolute value of the y-coordinate for node 2 (i.e., y2) minus the y-coordinate for node 3 (i.e., y3); and so on. Process 210 can further include storing, for each node-to-node segment, the node-to-node distance (d) and the shape types (i.e., layers) having edges intersecting with LDM 310 at each node. For example, for Sa, a first edge intersecting with LDM 310 is a thick oxide edge at node 1 and a second edge intersecting with LDM 310 is a silicon open edge at node 2; for Sb, a first edge intersecting with LDM 310 is a silicon open edge at node 2 and a second edge intersecting with LDM 310 is an active silicon (bulk) edge at node 3; and so on. Process 210 can be performed by processor 150 (e.g., automatically or in response to a user request via GUI 132).

The method can further include accessing the design rules database 111 and, particularly, subset 112 thereof and executing a shape-based rule selection algorithm (as discussed below) with respect to each node-to-node segment (S) in order to identify and assign specific design rules (R) to each of the node-to-node segments (S) (see processes 212 and 216). That is, given the shape types at the first and second edges of the two nodes of any given node-to-node segment, the applicable design rule (R) for that segment is identified, the distance specification (D) given the design rule is determined, and the design rule and distance specification are assigned to the segment. More specifically, as mentioned above, subset 112 of design rules (R) included in the design rules database 111 are shape-dependent and include, but are not limited to, design rules that establish distance specifications (i.e., technology requirements) for the widths of specific types of shapes in a layout (i.e., width rules 113(a)), for the size of spaces between shapes of the same or different types in a layout (i.e., space rules 113(b)), and for amount of allowable overlap between shapes of the same or different types in a layout (i.e., overlap rules 113(c)). The shape-based rule section algorithm can look at the shape types (i.e., the layers) and determine what rule to apply.

For example, the shape-base rule selection algorithm can proceed according to the following steps:
Step 1: Are the layers the same?
   (a) If yes, is there the same layer between the nodes?
      (1) If no, apply a space rule defined for the different layers?
      (2) If yes, apply a width rule defined for the same layer?
   (b) If no, apply either a space rule or an overlap rule (go to Step 2).
Step 2: Does one layer cover the other layer?
   (a) If no, apply a space rule defined for the layers. If no space rule is available, choose previous node space and add flag to value.
   (b) If yes, apply an overlap rule defined for the layers (node with one edge is first). If no rule available, choose previous node space and add flag to value

Processes 212-216 can be performed by processor 150 (e.g., automatically or in response to a user request via GUI 132).

After design rules (R) and distance specifications (D) are assigned to the segments (S), respectively, the method can include generating a first table (T1) including the design rules (R) and distance specifications (D) applicable to the node-to-node segments (S), respectively (see process 218 and FIG. 3.4). T1 can also include the node-to-node distances (d) for the node-to-node segments (S), respectively. Process 218 can further include storing T1 in storage medium 102 for use during subsequent process steps. Process 218 can also include outputting T1 to a user for review. For example, T1 can be displayed via GUI 132. Additionally, or alternatively, T1 could be output to a user for review in any other suitable manner (e.g., printed, emailed, messaged, etc.). Process 218 can be performed by processor 150 (e.g., automatically or in response to a user request via GUI 132).

The method can further include receiving, by processor 150 (e.g., via GUI 132), user inputs including, but not limited to, selection of a subset of the node-to-node segments (S) to be analyzed, any compacted distance specifications (C) proposed for any of the node-to-node segments (S) in the subset, as well as any user notes that should be considered during subsequent analysis. This user-provided information can be used, by processor 150, to generate a second table (T2) including the user-selected node-to-node segments (S) in the subset and, for each node-to-node segment (S) in the subset, the applicable design rule (R) and either the distance specification (D) associated with the applicable design rule or a compacted distance specification (C) proposed by the user (see process 220 and FIG. 3.5). As illustrated in FIG. 3.5, in the example provided the node-to-node segments Sa-Sf, Sh, and Sj-Sq have been selected. Additionally, compacted distance specifications (C) and user notes have been input for segments Sc, Se, Sj and Sm. Process 220 can further include storing T2 in storage medium 102 for use during subsequent processing. Process 220 can also include outputting T2 to a user for review. Process 220 can be performed by processor 150 (e.g., automatically or in response to a user request via GUI 132).

The method can further include combining T1 and T2 to generate an output table (T3) including, for each node-to-node segment (S) of the subset set forth in T2, the node-to-node distance (d) calculated at process 210, the design rule (R) assigned at process 216, and either the distance specification (D) associated with the design rule or a compacted distance specification (C) (as indicated in T2) (see process 224 and FIG. 3.6). Optionally, T3 can also include a total sum (t) 351 of all node-to-node distances (d) for the node-to-node segments (S) within the subset shown in T3 and a total sub (T) 352 of the distance specifications (D) or, if applicable, compacted distance specifications (C) for the node-to-node segments (S) within the subset shown in T3. Process 224 can also include storing T3 in storage medium 102 for further use during subsequent process steps. Process 224 can also include outputting T3 to a user for review. For example, T3 can be displayed via GUI 132. Additionally, or alternatively, T3 could be output to a user for review in any other suitable manner (e.g., printed, emailed, messaged, etc.). Processes 222-224 can be performed by processor 150 (e.g., automatically or in response to a user request via GUI 132).

The method can further include performing an analysis of design layout 301 using the information presented in T3 and making recommendations regarding design optimization (see process 226). For example, if it is determined that the trade-off between size scaling and power and performance is acceptable (e.g., if the proposed compaction will not result in a reduction of power and/or performance below previously established technology and/or design specifications), then a recommendation to proceed with compaction can be made. Process 226 can be performed manually (e.g., by the user) and/or automatically by processor 150 and can include, for example, proposing possible design rule trade-offs and comparing such design rule trade-offs to stated goals for assessment.

The method can further include, based on design optimization recommendations made at process 226, generating a revised design layout for the IC component (e.g., a compacted design layout for the IC component) and storing the revised design layout in storage medium 102 for user in subsequent processing (see process 228). Iterative design processing can further be performed in order to generate a final integrated circuit design layout (also referred to herein as a final IC design layout or final IC layout), which includes the revised design layout for the IC component (see process 232). The final IC design layout can further be released to manufacturing and ICs can be manufactured according to the final IC design layout (see process 236).

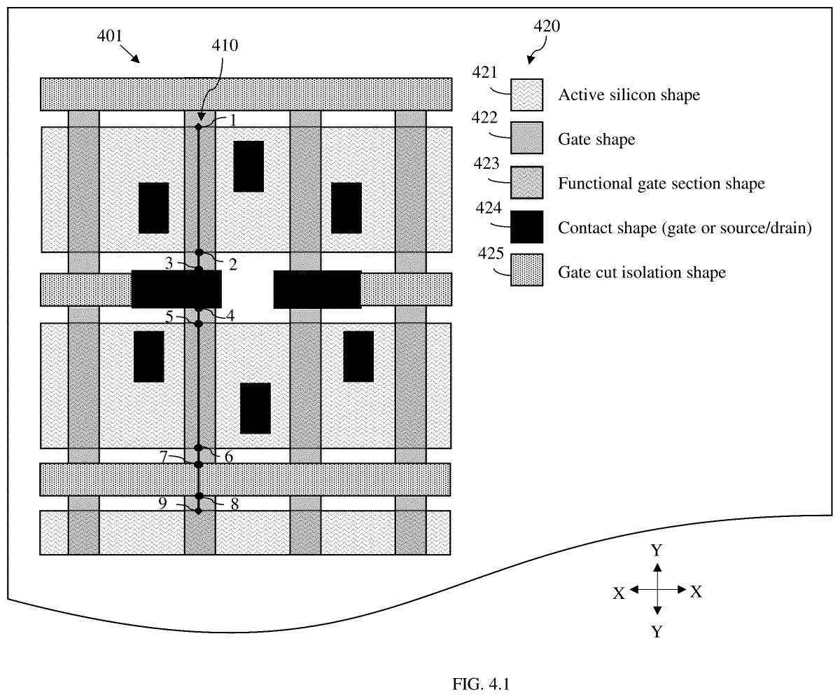

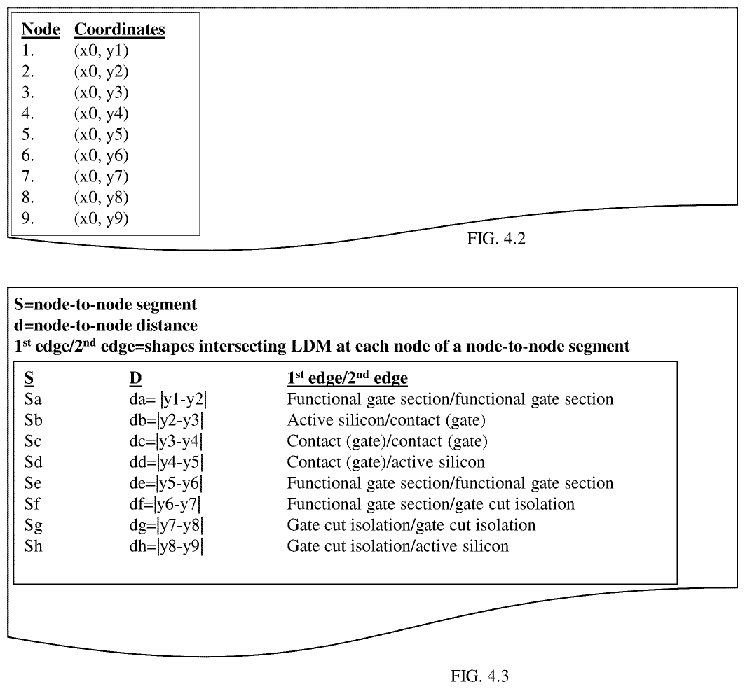

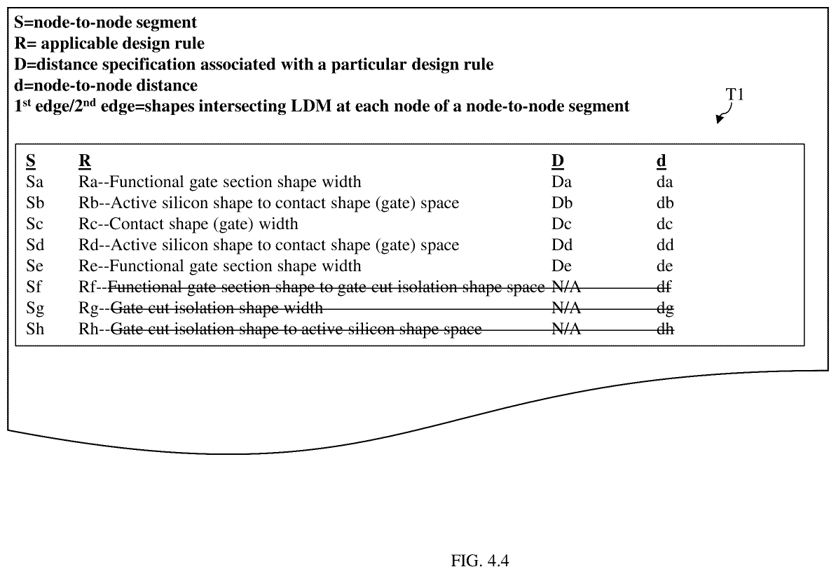

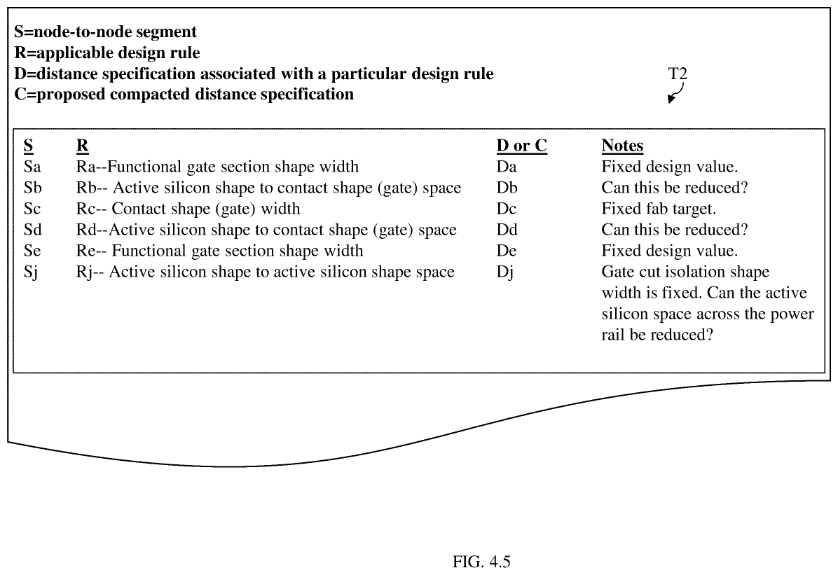

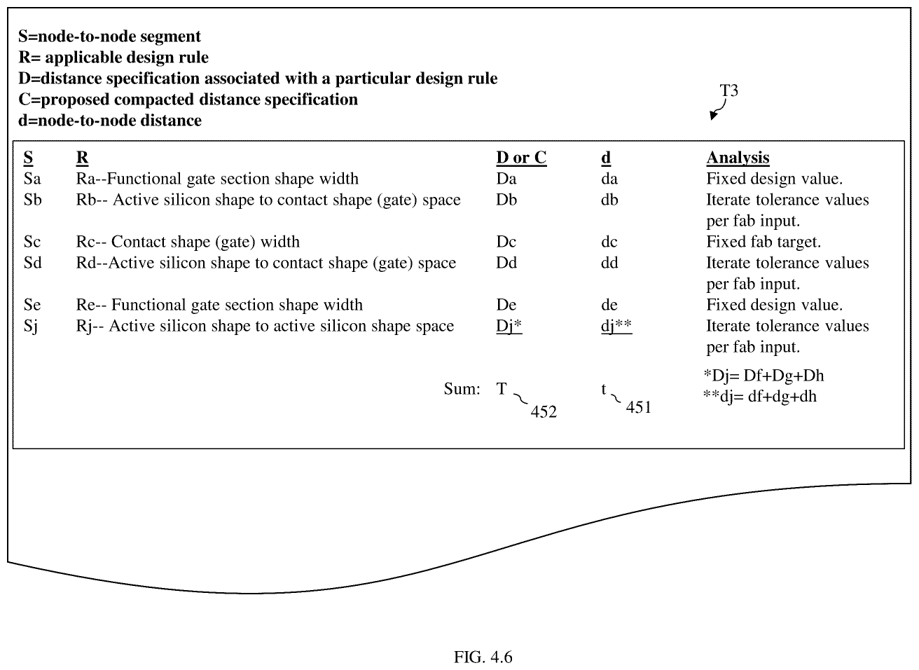

FIGS. 4.1-4.6 illustrate another example of implementation of the method of FIG. 2. Referring to FIG. 2 in combination with FIGS. 4.1-4.6, the method can similarly include, in response to user inputs (e.g., designer inputs via GUI 132), displaying a previously generated design layout 401 to be analyzed (see process 202 and FIG. 4.1). In this case, design layout 401 represents a single standard cell, which is being designed for inclusion in a cell library (e.g., of a PDK), which includes multiple interconnected devices, and which is being analyzed to consider the feasibility of reducing the cell track height. Shapes 420 in the design layout 401 include, for example, an active silicon shape 421, a gate shape 422, a functional gate section shape 423 (which defines the shape of a channel region), a contact shape 424 (e.g., for either a gate or source/drain) and a gate cut isolation shape 425.

Processes 204-228 can be performed in essentially the same manner as described above with regard to FIGS. 3.1-3.6. Specifically, an LDM 410 (also referred to herein as an ARC) can be placed over at least a portion of design layout 401 shown on GUI 132 (see process 204 and FIG. 4.1). Design layout 401 can be scanned to identify all locations where edges of any of the shapes 420 in the design layout 401 intersect LDM 410. Nodes (e.g., see nodes 1-9) can then be inserted into LDM 410 at each of the intersecting locations (see process 206 and FIG. 4.1). Next, coordinate information for nodes 1-9 on LDM 410 can be identified and stored (e.g., in storage medium 102) for use in subsequent processing (see process 208 and FIG. 4.2). Additionally, node-to-node distances (d) for each node-to-node segment (S) (i.e., distances da-dh for segments Sa-Sh) on LDM 410 can be calculated using the previously determined coordinate information (see process 210 and FIG. 4.3). Then, the design rules database 111 and, particularly, subset 112 thereof can be accessed and a shape-based rule selection algorithm (as discussed above) can be executed with respect to each node-to-node segment (S) in order to identify and assign specific design rules (R) and corresponding design specifications (D) to each of the node-to-node segments (see processes 212 and 216).

After design rules (R) and corresponding design specifications (D) are assigned to the segments (S), respectively, a first table (T1) including the design rules (R) applicable to the node-to-node segments (S), respectively, can be generated (see process 218 and FIG. 4.4). T1 can also include the node-to-node distance specifications (D) and the node-to-node distances (d) for the node-to-node segments (S), respectively. T1 can be stored in storage medium 102 for use during subsequent processing and also output to a user for review (e.g., displayed via GUI 132 or otherwise output).

User inputs in response to T1 can include, but are not limited to, selection of a subset of the node-to-node segments (S) to be analyzed, any compacted distance specifications (C) proposed for any of the node-to-node segments (S) in the subset, as well as any user notes that should be considered during subsequent analysis. In this example, the selected node-to-node segments include Sa-Se and a new segment Sj, which combines Sf, Sg, and Sh. Then, T2 can be generated (see process 220 and FIG. 4.5). In this example, T2 identifies the user-selected node-to-node segments (S) in the subset (i.e., Sa-Se and Sj). Additionally, for each of Sa-Se, T2 identifies the applicable design rule (R) and either the distance specification (D) associated with the applicable design rule or a compacted distance specification proposed by the user. For Sj, T2 indicates the sum Dj of applicable design specifications for Df, Dg, and Dh and the sum dj of node-to-node distances df, dg, and dh for node-to-node segments Sf, Sg, and Sh. At process 220, T2 can also be stored in storage medium 102 for use during subsequent process and output to a user for review. Information acquired from T1 and T2 can then be combined to generate an output table (T3) (see process 224 and FIG. 4.6). T3 can include, for each node-to-node segment (S) of the subset set forth in T2, the node-to-node distance (d) calculated at process 210, the design rule (R) assigned at process 216, and either the distance specification (D) associated with the design rule or a compacted distance specification (C) (as indicated in T2). Optionally, T3 can also include a total sum (t) 451 of all node-to-node distances (d) for the node-to-node segments (S) within the subset shown T3 and a total sub (T) 452 of the distance specifications (D) or, if applicable, compacted distance specifications (C) for the node-to-node segments (S) within the subset shown in T3. At process 224, T3 can also be stored in storage medium 102 for use during subsequent process steps and further output to a user for review (e.g., via GUI 132 or otherwise).

An analysis of design layout 401 can then be performed using T3 and recommendations for design optimization can be made (see process 226). For example, if it is determined that the trade-off between reduction of the cell track height and power and performance is acceptable (e.g., if the proposed compaction will not result in a reduction of power and/or performance below previously established technology and/or design specifications), then a recommendation to proceed with compaction can be made. Process 226 can be performed manually (e.g., by the user) and/or automatically by processor 150 and can include, for example, proposing possible design rule trade-offs and comparing such design rule trade-offs to stated goals for assessment.

Based on the recommendations made at process 226, a revised design layout for the cell (e.g., a compacted design layout for the cell, also referred to herein as a revised cell layout or a compacted cell layout) can be generated and stored in storage medium 102 (see process 228). Iterative design processing can further be performed in order to generate a final design layout for the cell (also referred to herein as a final cell design layout) to be included in a cell library (e.g., of a PDK) and available for subsequent selection and placement in an IC design layout (see process 234). A final IC design layout (e.g., including the final design layout for the cell (also referred to herein as the final cell layout)) can be released to manufacturing and ICs can be manufactured according to the final IC design layout (see process 236).

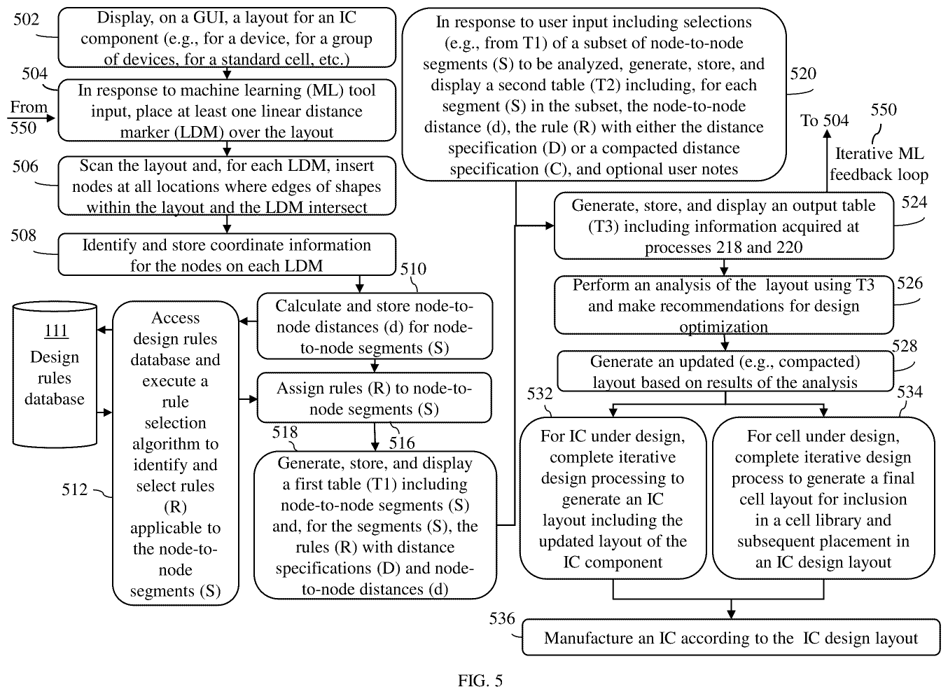

FIG. 5 is a modified version of the flow diagram of FIG. 2 and illustrates alternative method embodiments in which machine learning (ML) is employed to provide a more detailed analysis with a faster turnaround time that the previously described method embodiments. The process steps of the flow diagram of FIG. 5 are essentially the same as those set forth in FIG. 2 except as mentioned below.

Referring to the flow diagram of FIG. 5, the method can include, in response to user inputs (e.g., designer inputs via GUI 132), displaying a previously generated design layout 601 to be analyzed (see process 502 and FIG. 6). For purposes of illustration, design layout 601 is essentially the same as design layout 301 of FIG. 3.1 described above. That is, design layout 601 represents a single field effect transistor (FET) implemented in fully-depleted silicon-on-insulator (FDSOI). Shapes 620 in the design layout 601 include, for example, a thick oxide shape 621, a p-type implant region shape 622, a silicon open shape 623, an active silicon shape 624 (e.g., either in SOI or in a bulk region of the FDSOI structure), a gate shape 625, a functional gate section shape 626 (which defines the shape of the FET channel region), and a contact shape 627 (e.g., either on the active silicon (SOI) or on the active silicon (bulk)).

In this case, at process 504, multiple LDMs can be automatically placed by a ML tool 135 over different areas of design layout 601 (see FIG. 6). One or more LDMs can be placed so that they are oriented in a first direction (y-direction) (see example LDMs 610y) and/or in a second direction perpendicular to the first direction (x-direction) (see example LDM 610x). Optionally, one or more of the LDMs could also be placed so as to be oriented is some other direction (e.g., diagonally across design layout 601) (not shown). Those skilled in the art will recognize that an ML tool is an algorithmic application of artificial intelligence configured to have the ability to learn without human input. Such ML tools are known in the art and, thus, the details thereof have been omitted from this specification in order to allow the reader to focus on the salient aspects of the disclosed embodiments. ML tool 135 can be a sub-tool of the design layout analysis tool 131 (as illustrated) or, alternatively, can be a discrete ML tool (e.g., an additional EDA tool 130).

Processes 506-536 can proceed in essentially the same manner as processes 206-236 of FIG. 2 described above (e.g., as illustrated in FIGS. 3.1-3.6). However, in this case, the method can also include a ML feedback loop (see process 550) where T3 is feed back to the ML tool so that the analysis of the design layout is iterative. Specifically, based on the information set forth in T3, ML tool 135 determines placement locations for additional LDMs and processes 504-536 and 550 are iteratively repeated until conditions are sufficiently met based on pre-determined criteria and limiting values.

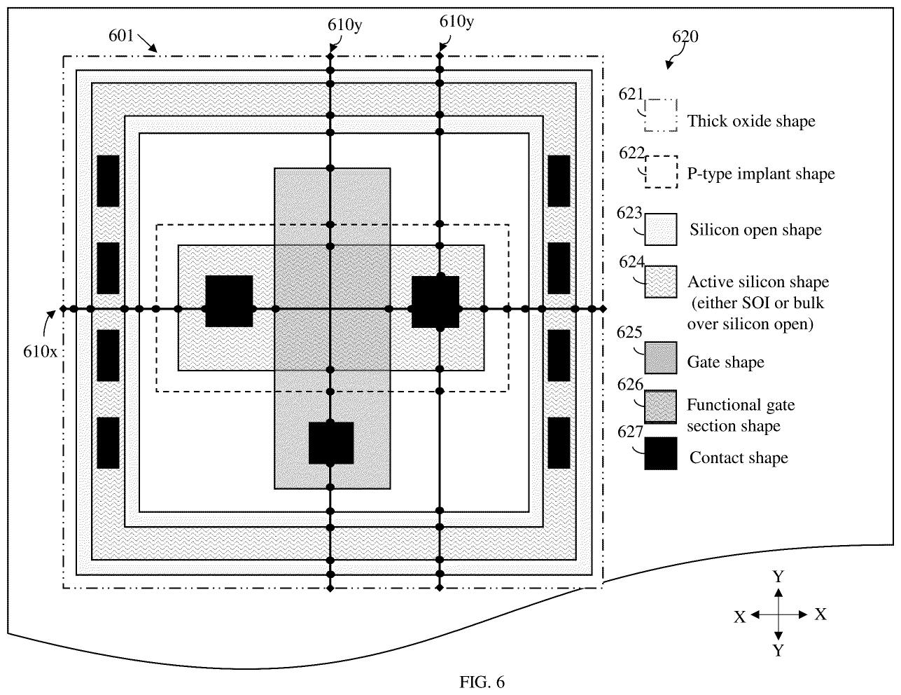

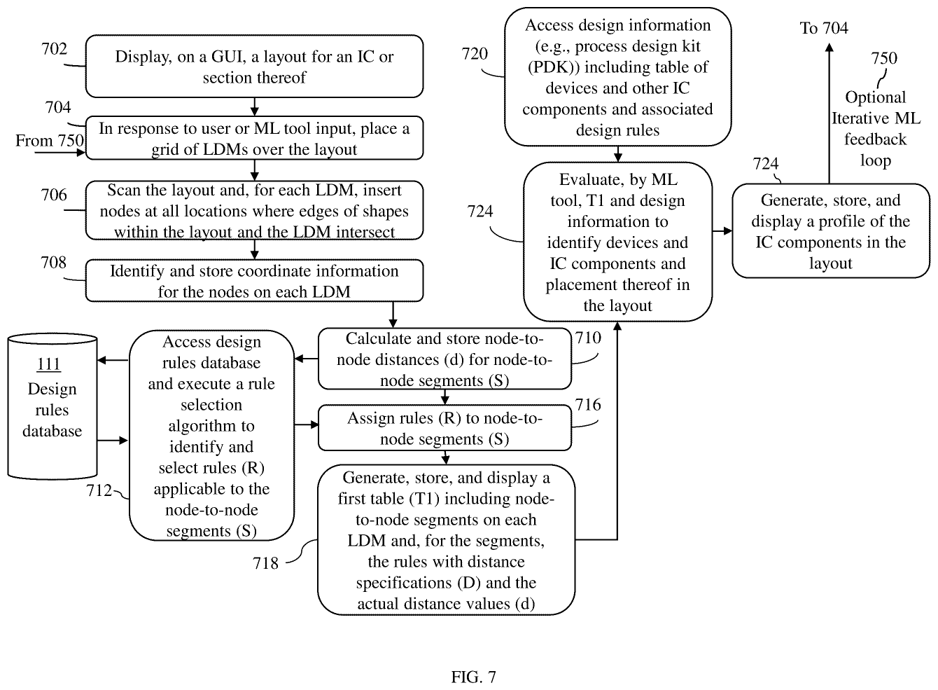

FIG. 7 is another modified version of the flow diagram of FIG. 2 and illustrates yet another alternative method embodiment in which LDMs and a ML tool 135 are employed for design layout profiling (e.g., identifying devices and other components within a design layout) as opposed to DTCO. The process steps of the flow diagram of FIG. 7 have some similar processes to those set forth in both FIG. 2 and FIG. 5, as discussed below.

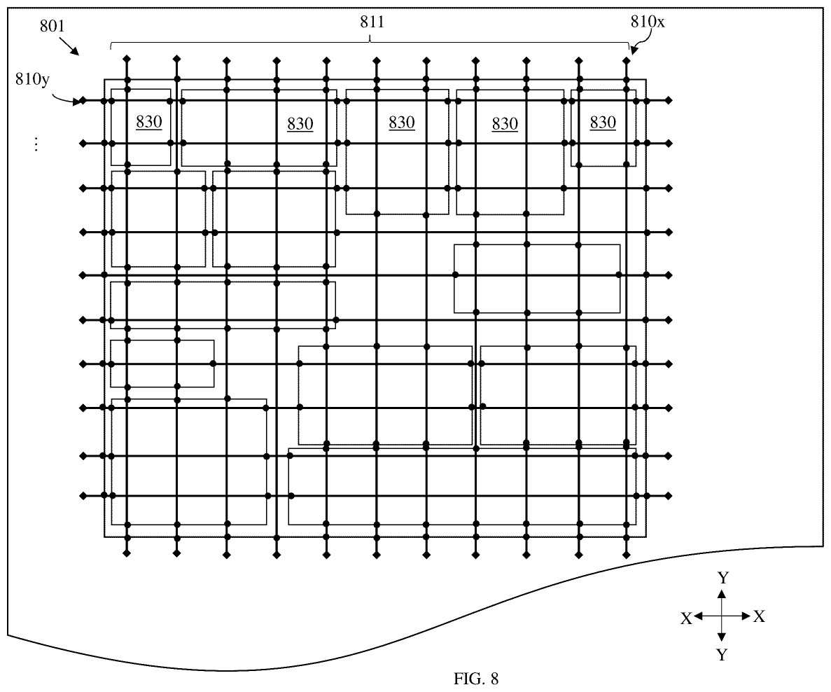

Referring to FIG. 7, the method can include, in response to user inputs (e.g., designer inputs via GUI 132), displaying a previously generated design layout 801 to be analyzed (see process 702 and FIG. 8). Design layout 801 can be, for example, a design layout for an entire IC or relatively large subsection thereof. Items 830 represent, for example, different IC components (e.g., devices, cells, etc.) placed within design layout 801. To avoid clutter in the drawing, shapes associated with different layers (e.g., active silicon, gates, isolation regions, etc.) in each of the different IC components 830 are not included in FIG. 8.

The method can include placing multiple LDMs arranged in a grid 811 over design layout 801 shown on GUI 132 (see process 704). The grid 811 can include multiple LDMs oriented in a first direction (y-direction) (see example LDMs 810y) and multiple LDMs oriented in a second direction (x-direction) perpendicular to the first direction (see example LDMs 810x). The grid 811 (including the number of LDMs 810y and 810x in oriented in each direction) and the distance between parallel LDMs) can, for example, be placed in response to user inputs or automatically by ML tool 135.

Processes 706-718 can proceed in essentially the same manner as processes 206-218 of FIG. 2, described above. It should be noted that at process 706 nodes will be inserted into the LDMs 810y and 810x at all intersections with edges of shapes within IC components 830. However, as mentioned above, shapes associated with different layers within each of the different IC components 830 are not shown to avoid clutter in FIG. 8. Thus, also to avoid clutter in FIG. 8, only those nodes at the intersections between the LDMs and edges of the IC components 830 are shown (not nodes at the intersections of the LDMs and shapes within the IC components 830). In any case, after T1 has been generated, stored and, optionally, output (at process 718), the method can include accessing, by processor 150, design information 140 (e.g., PDK 110) (see process 720). The accessed design information 140 can include, for example, the table 114 of devices or other IC components (e.g., groups of devices, cells, etc.) available at the particular technology node and, from the design rules database 111, design rules associated therewith include, but not limited to, the shape-dependent design rules that establish distance specifications (i.e., technology requirements) for the widths of specific types of shapes in a layout (e.g., design rules 113(a)-113(c) discussed above).

The method can further include evaluating, by processor 150 executing the ML tool 135, information contained in T1 generated at process 718 and design information 140 accessed at process 720 to identify IC components (e.g., of devices, groups of devices, cells, etc.) and placement thereof in the design layout 801 (see process 722). The method can further include, based on the evaluation, generating, by processor 150, a profile (P) of the IC components in design layout 801 (see process 724). Process 724 can further include storing the profile (P) in storage medium 102 for use during subsequent processing and, optionally, outputting the profile (P) to a user for review. For example, the profile (P) can be displayed via GUI 132. Additionally, or alternatively, the profile (P) could be output to user for review in any other suitable manner (e.g., printed, emailed, messaged, etc.).

Additionally, the method can include a ML feedback loop (see process 750) where the profile (P) is feed back to the ML tool 135 so that the analysis of the design layout is iterative. Specifically, based on the information set forth in the profile (P), ML tool 135 determines placement of another grid (e.g., including the number of LDMs oriented in each of the x and y directions and the spacing between LDMs in the x and y directions) and processes 706-750 are iteratively repeated until conditions are sufficiently met based on pre-determined criteria and limiting values

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Embodiments disclosed herein may be a system, a method, and/or a computer program product. The computer program product may include a computer readable storage medium (or media) having computer readable program instructions thereon for causing a processor to carry out aspects of the disclosed embodiments.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the disclosed embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the disclosed embodiments.

Aspects of the disclosed embodiments are described herein with reference to flowchart illustrations and/or block diagrams of methods, apparatus (systems), and computer program products according to disclosed embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various disclosed embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

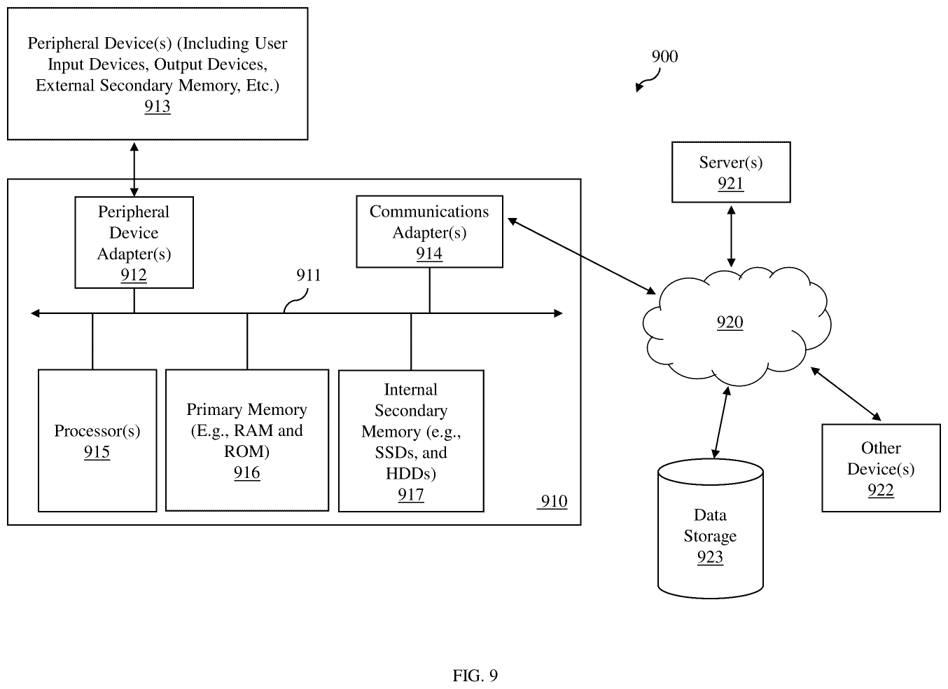

An illustrative hardware environment 900 for implementing aspects of the disclosed systems, methods and computer program products is depicted in FIG. 9. Generally, the hardware environment can include at least one computing device 910 (also referred to herein as a computer). The computer 910 can be, for example, a desktop, laptop, tablet, mobile computing device, etc. The computer 910 can include at least one bus 911. The bus 911 can be connected to various other components of the computer 910 and can be configured to facilitate communication between those components.

The computer 910 can include various adapters. The adapters can include one or more peripheral device adapters 912, which are configured to facilitate communications between one or more peripheral devices 913, respectively, and the bus 911. The peripheral devices 913 can include user input devices configured to receive user inputs. User input devices can include, but are not limited to, a keyboard, a mouse, a microphone, a touchpad, a touchscreen, a stylus, bio-sensor, a scanner, or any other type of user input device. The peripheral devices 913 can also include additional input devices, such as external secondary memory devices (as discussed in greater detail below). The peripheral devices 913 can also include output devices. The output devices can include, but are not limited to, a printer, a monitor, a speaker, or any other type of computer output device. The adapters can include one or more communications adapters 914 (also referred to herein as a computer network adapters), which are configured to facilitate communications between the computer 910 and one or more communications networks 920 (e.g., a wide area network (WAN), a local area network (LAN), the internet, a cellular network, a Wi-Fi network, etc.). Such communications network(s) 920 can, in turn, facilitate communications between the computer 910 and other system components on the communications network: remote server(s) 921, other device(s) 922 (e.g., computers, laptops, tablets, mobile phones, etc.), remote data storage 923, etc.

The computer 910 can further include at least one processor 915 (also referred to herein as a central processing units (CPU)). Optionally, each CPU 915 can include a CPU cache. Each CPU 915 can be configured to read and execute program instructions.

The computer 910 can further include memory and, particularly, computer-readable storage mediums. The memory can include primary memory 916 and secondary memory. The primary memory 916 can include, but is not limited to, random access memory (RAM) (e.g., volatile memory employed during execution of program operations) and read only memory (ROM) (e.g., non-volatile memory employed during start-up). The RAM can include, but is not limited to, dynamic random access memory (DRAM), static random access memory (SRAM), or any other suitable type of RAM. The ROM can include, but is not limited to, erasable programmable read only memory (EPROM), flash memory, electronically erasable programmable read only memory (EEPROM), programmable read only memory (PROM), or any other suitable type of ROM. The secondary memory can be non-volatile. The secondary memory can include internal secondary memory 917, such as internal solid state drive(s) (SSD(s)) and/or internal hard disk drive(s) (HDD(s), installed within the computer 910 and connected to the bus 911. The secondary memory can also include external secondary memory connected to or otherwise in communication with the computer 910 (e.g., peripheral devices). The external secondary memory can include, for example, external/portable SSD(s), external/portable HDD(s), flash drive(s), thumb drives, compact disc(s) (CD(s)), digital video disc(s) (DVD(s)), network-attached storage (NAS), storage area network (SAN), or any other suitable non-transitory computer-readable storage media connected to or otherwise in communication with the computer 910. The different functions of primary and secondary memory are well known in the art and, thus, the details thereof have been omitted from this specification in order to allow the reader to focus on the salient aspects of the disclosed embodiments.

In some embodiments, program instructions for performing the disclosed method or a portion thereof, as described above, can be embodied in (e.g., stored in) secondary memory accessible by the computer 910. When the program instructions are to be executed (e.g., in response to user inputs), required information (e.g., the program instructions and other data) can be loaded into the primary memory (e.g., stored in RAM). The CPU 915 can read the program instructions and other data from the RAM and can execute the program instructions. In other embodiments, a client-server model can be employed. In this case, the computer 910 can be a client and a remote server 921 in communication with the computer 910 over a network 920 can provide, to the client, a service including execution of program instructions for performing the disclosed method or a portion thereof, as described above, in response to user inputs the computer 910.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
calculating, by a processor, node-to-node distances for node-to-node segments on a linear distance marker overlaying a layout for an integrated circuit component, wherein nodes are located at intersections between the linear distance marker and edges of shapes in the layout;
generating, by the processor, a first table including design rules applicable to the node-to-node segments, respectively, wherein the first table further includes node-to-node distance specifications and the node-to-node distances for the node-to-node segments, respectively; and
generating, by the processor, an output table including, for each node-to-node segment of a subset of the node-to-node segments, a corresponding node-to-node distance, a corresponding design rule, and one of a corresponding distance specification and a corresponding compacted distance specification.

2. The method of claim 1, wherein the integrated circuit component includes any of a device, a group of devices, and a cell.

3. The method of claim 1, wherein the design rules are shape-dependent and include any of overlap, space, and width rules.

4. The method of claim 1, further comprising:
placing, by the processor in communication with a graphic user interface, the linear distance marker over the layout, wherein the placing is in response to user input; and
scanning, by the processor, the layout to insert the nodes at the intersections.

5. The method of claim 4, further comprising identifying, by the processor, coordinate information for the nodes on the linear distance marker, wherein the calculating of the node-to-node distances is performed using the coordinate information.

6. The method of claim 1, further comprising assigning, by the processor, the design rules to the node-to-node segments on the linear distance marker, wherein the assigning includes accessing a design rules database and executing a shape-based rule selection algorithm with respect to each node-to-node segment.

7. The method of claim 1, further comprising, before the generating of the output table:
receiving, through a graphic user interface, user inputs including selection of the subset and any compacted distance specifications for any of the node-to-node segments in the subset; and
generating, by the processor, a second table including, for each node-to-node segment in the subset, the corresponding design rule and the one of the corresponding distance specification and the corresponding compacted distance specification,
wherein the generating of the output table includes calculating a first sum of node-to-node distances and a second sum of distance and compacted distance specifications for all of the node-to-node segments in the subset, wherein the output table includes the first sum and the second sum.

8. The method of claim 1, further comprising:
performing an analysis of the layout using the output table; and
generating a revised layout for the integrated circuit component based on results of the analysis.

9. The method of claim 8, wherein, for an integrated circuit under design, the method further includes:
performing iterative design processing to generate a final integrated circuit layout incorporating the revised layout; and
manufacturing an integrated circuit according to the final integrated circuit layout.

10. The method of claim 8,
wherein, for a cell under design, the method further includes performing iterative design processing to generate a cell layout based on the revised layout and storing the cell layout with the cell in a cell library, wherein the cell is selectable for inclusion in a final integrated circuit layout; and
manufacturing an integrated circuit according to the final integrated circuit layout.

11. A method comprising:
placing, by a processor executing a machine learning tool, multiple linear distance markers over a layout for an integrated circuit component;
calculating, by the processor, node-to-node distances for node-to-node segments on the linear distance markers, wherein nodes are located at intersections between the linear distance markers and edges of shapes in the layout;
generating, by the processor, a first table including design rules applicable to the node-to-node segments, respectively, wherein the first table further includes distance specifications and the node-to-node distances for the node-to-node segments, respectively;
generating, by the processor, an output table including, for each node-to-node segment of a subset of the node-to-node segments, a corresponding node-to-node distance, a corresponding design rule, and one of a corresponding distance specification and a corresponding compacted distance specification; and
establishing, by the processor, an iterative machine learning feedback loop where the machine learning tool receives the output table and repeats the placing of the linear distance markers.

12. The method of claim 11, further comprising:
scanning, by the processor, the layout to insert the nodes at the intersections;
identifying, by the processor, coordinate information for the nodes on the linear distance markers, wherein the calculating of the node-to-node distances is performed using the coordinate information; and
assigning, by the processor, the design rules to the node-to-node segments on the linear distance markers, wherein the assigning includes accessing a design rules database and executing a shape-based rule selection algorithm with respect to each node-to-node segment.

13. The method of claim 11, further comprising, before the generating of the output table:
receiving, through a graphic user interface, user inputs including selection of the subset and any compacted distance specifications for any of the node-to-node segments in the subset; and
generating, by the processor, a second table including, for each node-to-node segment in the subset, the corresponding design rule and the one of the corresponding distance specification and the corresponding compacted distance specification,
wherein the generating of the output table includes calculating a first sum of node-to-node distances and a second sum of distance and compacted distance specifications for all of the node-to-node segments in the subset, wherein the output table includes the first sum and the second sum.

14. The method of claim 11, further comprising:
performing an analysis of the layout using the output table; and
generating a revised layout for the integrated circuit component based on results of the analysis.

15. The method of claim 14, wherein, for an integrated circuit under design, the method further includes:
performing iterative design processing to generate a final integrated circuit layout incorporating the revised layout; and
manufacturing an integrated circuit according to the final integrated circuit layout.

16. The method of claim 14, wherein, for a cell under design, the method further includes:
performing iterative design processing to generate a cell layout based on the revised layout and storing the cell layout with a cell in a cell library, wherein the cell is selectable for inclusion in a final integrated circuit layout; and
manufacturing an integrated circuit according to the final integrated circuit layout.

17. A method comprising:
placing, by a processor, a grid over a layout for at least a section of an integrated circuit, wherein the grid includes linear distance markers arranged in a first direction and in a second direction perpendicular to the first direction;
calculating, by the processor, node-to-node distances for node-to-node segments on the linear distance markers of the grid overlaying the layout, wherein nodes are located at intersections of the linear distance markers and edges of shapes in the layout;
generating, by the processor, a table including design rules applicable to the node-to-node segments, respectively, wherein the table further includes distance specifications and the node-to-node distances for the node-to-node segments, respectively;
evaluating, by the processor, the table and process design kit information to identify components within the layout; and
generating, by the processor, a profile of the components in the layout.

18. The method of claim 17, further comprising:
scanning, by the processor, the layout to insert the nodes at the intersections;
identifying, by the processor, coordinate information for the nodes on the linear distance markers, wherein the calculating of the node-to-node distances is performed using the coordinate information; and
assigning, by the processor, the design rules to the node-to-node segments on the linear distance markers, wherein the assigning includes accessing a design rules database and executing a shape-based rule selection algorithm with respect to each node-to-node segment.

19. The method of claim 17, wherein the placing is performed based on inputs from any of a user and a machine learning tool and wherein the evaluating is performed by a machine learning tool.

20. The method of claim 17, further including establishing, by the processor, an iterative machine learning feedback loop between the generating of the profile and the placing of the grid.
